(19) United States
(12) Patent Application Publication
(10) Pub. No.: US 2008/0067218 A1
(43) Pub. Date: Mar. 20, 2008

(54) Method and Computer Program for the Self-Assembly of a Nanostructure

(76) Inventors: Hakan Olin, Sundsvall (SE); Bjorn Hogberg, Sundsvall (SE); Lotten Glans, Sundsvall (SE)

Correspondence Address: DILWORTH & BARRESE, LLP, 333 EARLE OVINGTON BLVD., SUITE 702, UNIONDALE, NY, 11553, US

(21) Appl. No.: 11/587,329

(22) PCT Filed: Apr. 20, 2005
(86) PCT No.: PCT/SE05/00587

§ 371 Date: Aug. 29, 2007

(30) Foreign Application Priority Data
Apr. 20, 2004 (SE) 0401016-1

(51) Int. Cl. B23K 31/00; H01L 21/00

(52) U.S. Cl. 228/180.1; 438/22; 977/885; 257/E21.001

(57) ABSTRACT

Method for assembling a micro-, sub-micro- or nano-scale structure includes the steps of providing a set of cells (1A-5A) designed to assemble into a cell structure (C) in a predetermined order. The set of cells (1A-5A) are brought into contact with at least one seed so that a cell structure (C) grows from the seed(s). Before bringing the set of cells into contact with at least one seed, the method includes the step of mixing the set of cells (1A-5A) with at least one set of size-control-units (1B-11B) designed to assemble into a size-control-structure (U) in the vicinity of the cell(s) structure (C) in a predetermined order. The first set of cells (1A-5A) are also mixed with stop blocks (S) designed to prevent further growth of a cell structure (C) when a particular cell in the cell structure (C) becomes substantially adjacently located to a particular size-control-unit in the size-control-structure (U) by attaching to that particular cell and size-control-unit.-.

### TECHNICAL FIELD OF THE INVENTION AND PRIOR ART

The present invention concerns a method for assembling a micro-, sub-micro- or nano-scale structure, and an electronic or a photonic structure, mechanism or device or microelectromechanical system assembled using such a method. The invention also relates to a computer program containing computer program code means for making a computer or processor simulate such a method.

Traditionally integrated circuit component features are defined and delineated using a top-down approach such as a lithographic technique. Lithography is the process of transferring an image from a mask, layer by layer, to the surface of a semiconductor material for example via an ion implant, oxidation or metallization process between each successive image transfer.

Lithography techniques require a plurality of process steps each usually involving a resist mask. Overlay alignment of subsequent resist masks using special alignment features on the semiconductor material requires exact positioning of the mechanism supporting the semiconductor material. The overlay accuracy should preferably be considerably higher than the smallest feature size. However, mechanical alignment of the various resist masks necessary for the production of features of 0.5 μm or less in size is very difficult to achieve due to the mechanical nature of the overlay alignment process. Lithography is therefore an extremely slow and complicated method of fabricating an electronic device, and is becoming increasingly expensive as the size of electronic device continues to decrease.

The bottom-up approach where structures are formed atom-by-atom, molecule-by-molecule or component-by-component, by spontaneous self-assembly due to an interaction, such as a chemical reaction, between the individual atoms, molecules or components is becoming more popular as an alternative to the top-down approach for the fabrication of micro-, sub-micro- and nano-systems.

Cells i.e. atoms, molecules or prefabricated components, have to be provided with a region having a property that will cause the cell to mate, i.e. physically or chemically join or fix together, with a region of another cell having a complementary property. The region may for example have a particular shape, surface property, charge, polarizability or magnetic dipole. The cells must be allowed to move with respect to one another so self assembly usually takes place in fluid phases or on smooth surfaces. One disadvantage of self-assembly techniques is that it can be difficult to control the direction, orientation and growth of the structures formed.

WO 9828320 discloses a method for the fabrication of micro- and nano-scale devices comprising the steps of fabricating first component devices on a first support, releasing at least one first component device from the first support, transporting the first component device to a second support, via a fluid for example, and attaching the first component device to the second support. The first component devices are coated with a specific deoxyribonucleic acid (DNA) sequence. The area of the second substrate where attachment of the first component device is desired is coated with the specific complementary DNA sequence. The second substrate and the first component devices are released into a solution and hybridisation between complementary DNA strands occurs. Hybridisation between complementary DNA strands grafts the first component devices onto their proper receptor sites on the second support. If further devices are to be subsequently grafted onto the second support then the second support has to be dried and the method has to be repeated which makes it time consuming, complex and expensive.

### SUMMARY OF THE INVENTION

The object of the present invention is to provide an inexpensive, effective and simple method for fabricating a micro-, sub-micro- or nano-scale structure, such as an electronic or photonic structure, mechanism or device, or micro-electromechanical system which allows the growth of the structure to be accurately controlled.

This object is fulfilled using a method comprising the steps given in claim 1 namely a method comprising the steps of providing a set of cells, i.e. organic or inorganic atoms, molecules or prefabricated components, which are designed to assemble into a cell structure in a predetermined order. The set of cells are brought into contact with at least one seed, i.e. a cell or a receptor site on a substrate which is configured to mate with a cell, so that a cell structure grows from the, or each, seed. The number of seeds depends on the application and the number of cell structures that are to be assembled. Before bringing the set of cells into contact with said at least one seed the method comprises the step of mixing the set of cells with at least one set of size-control-units that are designed to assemble into a size-control-structure in the vicinity of the, or each, cell structure in a predetermined order. The set of cells are also mixed with stop blocks that are designed to prevent further growth of a cell structure when a particular cell in the cell structure becomes substantially adjacently located to a particular size-control-unit in the corresponding size-control-structure by attaching themselves to that particular cell and that particular size-control-unit.

The growth of the cell structure is accurately controlled as further growth of the cell structure is automatically prevented once the cell structure reaches a certain size. Since the stop block can only attach itself to a particular cell and a particular size-control-unit it will only attach itself to the growing cell structure and its corresponding size-control-structure if that particular cell and size-control-unit become substantially adjacently located to one another during the growth of the cell structure and the size-control-structure. Growth of the cell structure will continue until the stop block is in place. A size-control-structure does not need to be immediately adjacent to the cell structure but it must be close enough to it to allow a stop block, which can be a single atom or molecule to be able to attach itself to both the cell structure and the corresponding size-control-structure.

The self-assembly of the cell structure is therefore programmable and the properties of the cells, their respective concentration in the mixture and the choice of seed(s) therefore constitute the program for self assembly. This method allows distinct engineered building blocks (cells) to be programmed to spontaneously organise themselves into complex structures in a controlled manner.

According to an embodiment of the invention the concentration of at least one particular type of cell, size-control-unit or stop block is either increased or decreased during the assembly process so as to increase the probability of correct assembly.

According to another embodiment of the invention the method further comprises the step of removing the size-control-units and/or the stop blocks once the cell structure has been assembled. The size-control-structures and/or stop blocks do not therefore need to be a permanent feature of the product being assembled but may be used merely to control the product's assembly process.

According to an embodiment of the invention the set of cells and the set of size-control-units comprise a prime number of cells/units respectively. Any number of cells and size-control-units can however be used as long as a particular cell will become substantially adjacently located to a particular size-control-unit once the cell structure has reached a predetermined growth stage. According to a further embodiment of the invention two or more sets of size-control-units are mixed with the set of cells. This provides more flexibility in choosing the size of the cell structure. For example if three sets of size-control-units are used the maximum height of a cell structure can be chosen to be equal to the height of the number of size-control-units in set 1 plus the number of size-control-units in set 2 plus the number of size-control-units in set 3.

According to another embodiment of the invention the cells and the size-control-units are substantially of the same thickness however the cells and the size-control-units can be of different thicknesses if the growth rates of the cell structure and the corresponding size-control-structures are different.

According to yet another embodiment of the invention the method comprises the step of bringing a fluid, i.e. a liquid or a gas or a gas-liquid mixture, containing the cells, size-control-units and stop blocks into contact with the, or each, seed.

According to a further embodiment of the invention at least one cell/size-control-unit has at least one region having a property that causes that region of the cell/size-control-unit to mate with another region of a cell/size-control-unit respectively having a complementary property. The property may for example be one of the following: shape, a surface property such as a hydrophilic/hydrophobic surface, a hydrogen bonding surface, a van der Waals interaction surface, metallic binding surfaces, covalent or ionic binding surfaces, electric charge or magnetic dipole or a combination thereof. The cells may be coated with a coating such as a nucleic acid so that when cells are mixed together complementary regions of the cells mate by transcription i.e. genetic information is transferred from one cell to another. Alternatively the mating of complementary surface coatings may cause a chemical reaction that forms a substance that bonds the two cells together.

According to an embodiment of the invention said at least one region is a DNA-region that is arranged to bind to another specific DNA-region. According to another embodiment of the invention at least one cell/size-control-unit has a plurality of DNA-regions that are each arranged to bind to another specific DNA-region.

This means that each cell/size-control-unit can take part in several reactions. In its first reaction one cell/size-control-unit is bound to a second cell/size-control-unit thus passivating the first cell's/size-control-unit's DNA-region since double-stranded DNA is formed between the two cells/size-control-units. The conjoined cell/size-control-unit-structure, or dimer, then has to bond to a corresponding conjoined cell/size-control-unit-structure. This second reaction is more selective because two different DNA-regions on the dimer have to correspond to two DNA-regions on another dimer. The larger the structures, the more selective the reactions become.

According to an embodiment of the invention the method comprises the step of providing a stop block with at least one region that attracts at least one part of at least one cell so that a new cell structure grows from the stop block which consequently acts as a seed for the new cell structure. This means that not only the size of a cell structure can be controlled but also the actual architecture of the structure.

According to a further embodiment of the invention the method comprises the step of blocking a seed with a stop block (S) in order to inhibit or prevent growth on at least part of that seed. According to another embodiment of the invention the method comprises the step of removing a stop block from a cell or a seed in order to initiate or continue further growth of a cell structure.

According to an embodiment of the invention at least one cell structure and/or at least one size-control-structure, in entirety or in part, is/are used as a seed(s) for at least one other cell structure and/or at least one other size-control-structure in order to grow higher order structures. This means that a size-control-structure could be grown as a branch from a cell structure and that any single initial cell structure or size-control-structure could provide the stem for any number of cell structures or size-control-structures branching therefrom.

According to another embodiment of the invention the method comprises the step of copying information from a cell, size-control-unit or seed to form one or more new cells, size-control-units or seeds respectively in a manner analogous to the transcription and copying of DNA genes by ribonucleic acid (RNA) for example.

According to a further embodiment of the invention the method comprises the step of making cells from a single piece of starting material such as a semiconductor wafer with a predetermined thickness upon which circuitry components are created using conventional methods. Both sides of the wafer are then coated with a pattern of hydrophilic and hydrophobic regions for example and divided into cells.

According to a yet further embodiment of the invention at least one cell comprises an integrated circuit component, such as an LED, on one surface of the cell. The components of the circuit can for example interconnect with other necessary components in circuits contained on adjoining cells to provide the necessary connections to make an electronic device functional.

The inventive method may be used to create an atomic or molecular structure or an electronic device or to modify or repair defects in an existing atomic or molecular structure or electronic device. The method may also be used to fabricate and test a single element such as an electronic or photonic structure, mechanism or device or micro-electromechanical system independently before it is incorporated into a larger array of electronic or photonic or electromechanical elements. With existing techniques it is difficult to test any of the elements until the entire assembly is complete.

The present invention also concerns an electronic or photonic structure, mechanism or device or micro-electromechanical system that is assembled using a method according to any of the preceding claims. The present invention furthermore relates to a computer program containing computer program code means for making a computer or processor simulate a method according to any of the embodiments described above and a computer program product comprising such a computer program stored by means of a computer-readable medium. Such a simulation may be used to optimize an assembly process. It may for example help a user to design the necessary seed for an assembly process which will result in the growth of the desired cell structure.

Further advantages as well as advantageous features of the invention appear from the following description and the other dependent claims.

### BRIEF DESCRIPTION OF THE DRAWINGS

FIG. 1 shows three different ways in which a cell attach itself to another cell,

FIG. 2 shows a set of cells assembling into a structure in a predetermined order,

FIG. 3 shows a structure formed by programmed self-assembly according to an embodiment of the invention,

FIG. 4 depicts problems that can arise during a self assembly process,

FIG. 5 shows three different ways in which a cell can attach itself to two adjacent cells,

FIG. 6 shows a nano-structure formed by programmed self-assembly, and

FIG. 7 shows an example of an assembly process using basic nanosphere building blocks.

The following description and drawings are not intended to limit the present invention to the embodiments disclosed. The embodiments disclosed merely exemplify the principles of the present invention.

### DETAILED DESCRIPTION OF AN EMBODIMENT OF THE INVENTION

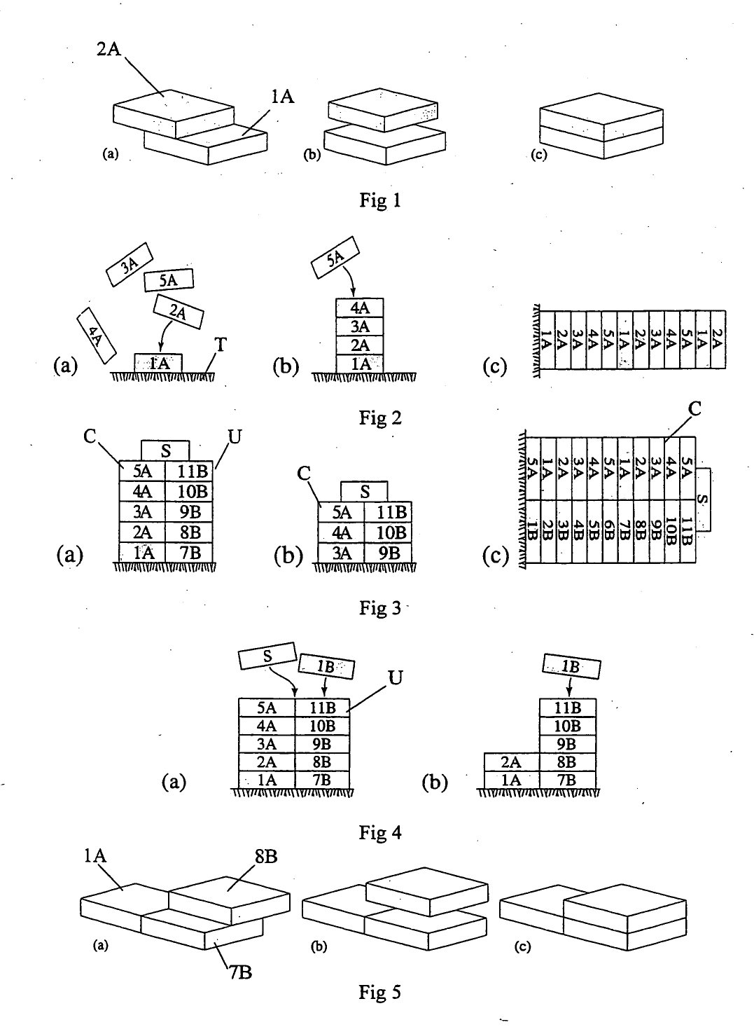

FIG. 1 shows a first cell 1A and second cell 2A represented by rectangles. The cells each comprise eight information-coded regions, four on each side. These regions are either hydrophilic or hydrophobic. The driving force for the self assembly is therefore the attraction of hydrophilic or hydrophobic surfaces to surfaces with the same hydrophobicity.

FIGS. 1a-c show three different ways in which an incoming second cell 2A can attach itself to the fixed first cell 1A. In figure la two of the second cell's 2A regions mate with two complementary regions of the first cell 1A. The second cell 2A therefore covers half of the first cell 1A. In FIG. 1b only one region of each cell mates and the second cell 2A covers one quarter of the first cell 1A. In FIG. 1c all four regions mate and the second cell 2A covers the entire first cell 1A. The orientation of the first cell 1A determines the overhang direction in FIGS. 1a and 1b.

FIG. 2 shows a set of cells 2A-5A dispersed in an inert fluid such as water, acetone or alcohol. This slurry contains enough fluid to allow the cells to slide across the top surface of a flexible or rigid substrate, T, and the seed, a type 1A cell in this case. The cells are designed to assemble into a column in a predetermined order. The cells may be copper atoms designed to assemble into a short atomic wire of a specific length for example.

When the slurry is applied over the substrate and the seed 1A a type 2A cell mates with the seed 1A, 3A mates with 2A, 4A mates with 3A and 5A mates with 4A to form a columnar cell structure C. If cell 1A is designed to mate with cell 5A the assembly process continues resulting in the formation of a periodic structure of uncontrollable height as shown in FIG. 2c.

FIG. 3 shows how the height of such a structure is controlled using a method according to the present invention. The first set of cells 1A-5A is mixed with a set of size-control-units 1B-11B. These size-control-units grow one on top of each other to form a columnar size-control-structure U. The first set of cells and the set of size-control-units are also mixed with stop blocks S that are designed to prevent further growth of the cell structure C when a cell of type 5A becomes substantially adjacently located to a size-control-unit of type 11B during the growth of the cell structure C and the size-control-structure U. The stop block S attaches itself to the type 5A cell and the type 11B size-control cell, overlapping both, and consequently prevents further cells from attaching themselves to these cells.

By using prime numbers of cells and size-control units cell structures C with different heights consisting of between 1 and 55 cells can be grown by varying the seed(s) from which the cell structure C and size-control-structure U are grown. The seeds therefore provide a vector blueprint for the self-assembly determining the magnitude and direction of the cell structure(s) that will be grown thereon.

Although a type 1A and a type 7B size-control-unit is used as the seed for the cell structure and the size-control-structure respectively, these could be replaced by a single larger seed having the combined mating properties of the type 1A cell and type 7B size-control-unit.

FIG. 3b shows that a cell structure C made up of three cells 3A, 4A and 5A can be grown if a type 3A cell and a type 9B size-control-unit are used as seeds. Similarly FIG. 3c shows that a cell structure C made up of 11 cells can be obtained using a type 5A cell and a type 1B size-control-unit as seeds. The same set of cells can therefore be used to build a wide variety of structures.

The cell structures C and size-control-structures U have been represented as columns however they could be of any shape the size-control-structure U could for example spiral around a columnar cell structure C. The size-control-units have been shown as having the same shape and size as the cells however this does not have to be the case. It is only important that a particular cell and a particular size-control-unit become substantially adjacently located to one another at some predetermined stage in the assembly process so that a stop block may be attached to said cell and size-control-unit to prevent further growth.

It should be noted that although cells have been used as seeds in the examples above, it is also possible to use a receptor site in a substrate, such as a motherboard as a seed. Furthermore it is not necessary to use a substrate; the assembly procedure could take place entirely within the fluid medium containing the cells, size-control-units and stop blocks.

FIG. 4a shows one of the problems that may arise using the inventive method namely that a type 1B size-control-unit may mate with the type 11B size-control-unit before the desired stop block S reaches the type 5A cell and type 11B size-control-unit resulting in undesired continued growth of the size-control-structure U and consequently also continued growth of the cell structure C. During the assembly process which occurs in a fluid the probability of a stop block S or a size-control-unit (1B) reaching the type 11B size-control-unit surface depends on the respective concentration of S and 1B in the fluid. The probability of correct assembly can therefore be increased by either increasing concentration of stop blocks S in the fluid or decreasing the concentration of 1B size-control-units in the fluid.

Another problem that can arise is shown in FIG. 4b namely that one structure, the size-control-structure U in this case, grows more quickly than the other. This problem can be avoided by changing the assembly rules for example by making it possible for a cell to attach itself to an underlying cell only if the underlying cell has an adjacent cell. FIG. 5 shows three basic ways a cell 8B can attach to two underlying adjacent cells 1A and 7B.

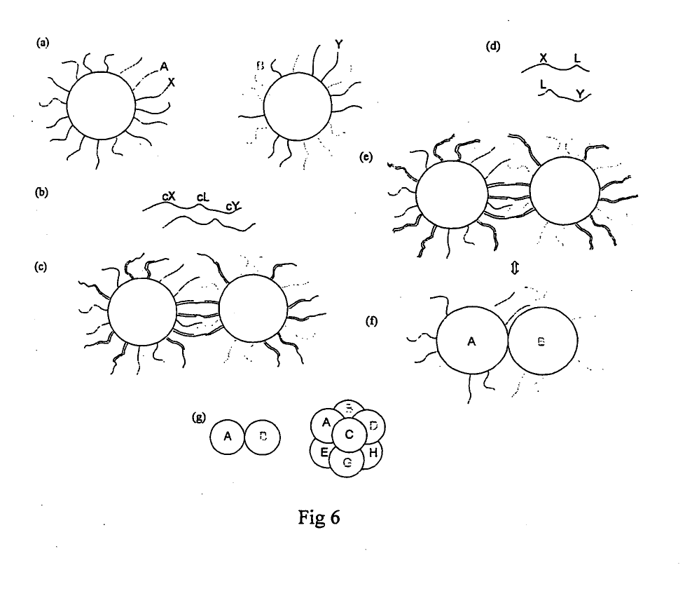

FIG. 6(a) shows two different nanospheres that are coated with two different types of single stranded DNA sequences; A, X and B, Y respectively. These nanospheres are mixed in solution and linker molecules, cX-cL-cY, consisting of a chain of complementary sequences to Y (cY) and X (cX) coupled by a sequence of bases (cL) are added (FIG. 6b). As the linker molecules are added, the two different types of nanospheres will adhere to one another, since the linker molecules hybridize with the complementary parts on the different nanospheres, making the nanospheres bind together (FIG. 6c) and aggregates of different sizes are thereby formed. By controlling the temperature of the solution the formation of dimers can be promoted.

The linker DNA is then rinsed away, preventing any further aggregation of the nanoparticles. Dimers can subsequently be separated from the other aggregates by centrifugation or some other mass separation technique. If necessary the “sticky” ends of the linker molecules could be passivated by adding a solution of LY and LX DNA (FIG. 6(d)-(e)). The only single stranded DNA that remains is of type A on one sphere and of type B on the other so the dimer in (e) is functionally equivalent to the one in (f).

The dimers produced in this way constitute simple building blocks with single stranded DNA of two different types, A and B, sticking out at different ends of the dimers. Using several iterations of this technique four-mers and eight-mers can be produced for utilization as more advanced bulding blocks for programmed self assembly (FIG. 6(g)).

Using the method described with reference to FIG. 6 a large number of different basic building blocks with specific DNA on different faces of the blocks can be created. Since the DNA building blocks are mixed together with blocks having complementary DNA, self-assembly will occur.

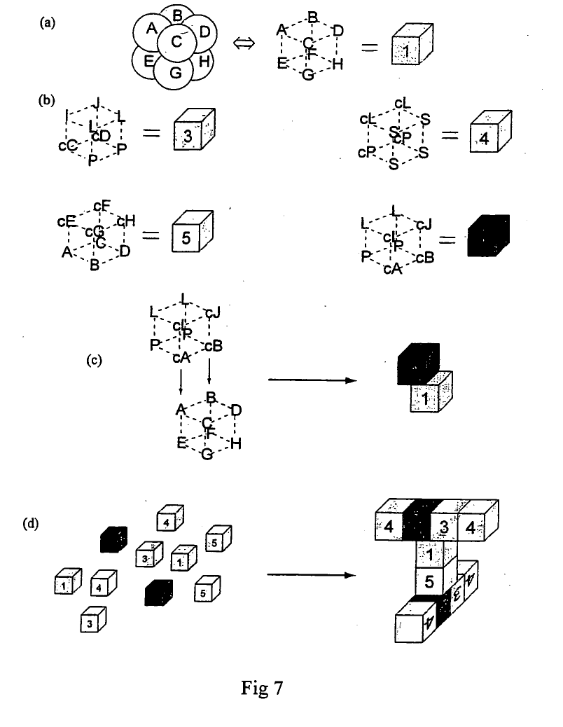

FIG. 7 shows an example of an assembly process using DNA-nanosphere eight-mers as building blocks. The eight-mers have eight specific DNA binding sites. These eight-mers can be thought of as cubes having functionalized surfaces (FIG. 7(a)). FIG. 7(b) depicts four more eight-mers. When mixed in solution the complementary DNA binding sites will bind to each other. FIG. 7(c) shows, for example, that the cA and cB strands on block 2 bind to the A and B strands on block 1. Mixing all of the building blocks together as shown in FIGS. 7(a) and 7(b) will lead to the formation of structures similar to the one shown in FIG. 7(d) for example.

The invention is of course not in any way restricted to the preferred embodiments thereof described above, but many possibilities to modifications thereof would be apparent to a man with ordinary skill in the art without departing from the basic idea of the invention as defined in the appended claims.

1. Method for assembling a micro-, sub-micro- or nano-scale structure comprising the steps of
providing a set of cells (1A-5A) that are designed to assemble into a cell structure (C) in a predetermined order and bringing the set of cells (1A-5A) into contact with at least one seed so that a cell structure (C) grows from the, or each, seed, wherein
before bringing the set of cells into contact with said at least one seeds the method comprises the step of mixing the set of cells (1A-5A) with at least one set of size-control-units (1B-11B) that are designed to assemble into a size-control-structure (U) in the vicinity of the, or each, cell structure (C) in a predetermined order, and with stop blocks (S) that are designed to prevent further growth of a cell structure (C) when a particular cell in the cell structure (C) becomes substantially adjacently located to a particular size-control-unit in the corresponding size-control-structure (U) by attaching themselves to that particular cell and that particular size-control-unit.

2. Method according to claim 1, wherein the concentration of at least one particular type of cell, size-control-unit or stop block is either increased or decreased during the assembly process.

3. Method according to claim 1, wherein it further comprises the step of removing the size-control-units (1B-11B) and/or the stop blocks (S) once the cell structure (C) has been assembled.

4. Method according to claim 1, wherein the set of cells (1A-5A) and the set of size-control-units (1B-11B) comprise a prime number of cells/units respectively.

5. Method according to claim 1, wherein the cells and the size-control-units are substantially of the same thickness.

6. Method according to claim 1, wherein it comprises the step of bringing a fluid containing the cells, size-control-units and stop blocks into contact with the, or each, seed.

7. Method according to claim 6, wherein the fluid is a liquid or a gas or a gas-liquid mixture.

8. Method according to claim 1, wherein at least one cell/size-control-unit has at least one region having a property that causes that region of the cell/size-control-unit to mate with another region of a cell/size-control-unit respectively having a complementary property.

9. Method according to claim 8, wherein the property is one of the following: shape, a surface property such as a hydrophilic/hydrophobic surface, a hydrogen bonding surface, a van der Waals interaction surface, metallic binding surfaces, covalent or ionic binding surfaces, electric charge or magnetic dipole or a combination thereof.

10. Method according to claim 8, wherein said at least one region is a DNA-region that is arranged to bind to another specific DNA-region.

11. Method according to claim 10, wherein at least one cell/size-control-unit has a plurality of DNA-regions that are each arranged to bind to another specific DNA-region.

12. Method according to claim 1, wherein it comprises the step of providing a stop block (S) with at least one region that attracts at least one part of at least one cell so that a new cell structure (C) grows from the stop block (S) which consequently acts as a seed for the new cell structure (C).

13. Method according to claim 1, wherein it comprises the step of blocking a seed with a stop block (S) in order to inhibit or prevent growth on at least part of that seed.

14. Method according to claim 1, wherein it comprises the step of removing a stop block (S) from a cell (1A-5A) or a seed in order to initiate or continue further growth of a cell structure (C).

15. Method according to claim 1, wherein at least one cell structure (C) and/or at least one size-control-structure (U), in entirety or in part, is/are used as a seed(s) for at least one other cell structure (C) and/or at least one other size-control-structure (U).

16. Method according to claim 1, wherein the method comprises the step of copying information from a cell, size-control-unit or seed to form one or more new cells, size-control-units or seeds respectively.

17. Method according to claim 1, wherein it comprises the step of making cells from a single piece of starting material such as a semiconductor wafer.

18. Method according to claim 1, wherein at least one cell comprises an integrated circuit device.

19. Electronic or photonic structure, mechanism or device, or micro-electromechanical system, assembled using a method according to claim 1.

20. Computer program containing computer program code means for making a computer or processor simulate a method according to claim 1.

21. A computer program product comprising a computer program stored by means of a computer-readable medium arranged to make a computer or processor execute a simulation according to claim 1.
